(19) United States
(12) Patent Application Publication
(10) Pub. No.: US 2014/0061871 A1
(43) Pub. Date: Mar. 6, 2014

(54) SEMICONDUCTOR DEVICE AND METHOD OF MANUFACTURING THE SAME

(71) Applicant: Kaoru NAGASAWA, Toyota-shi (JP)

(72) Inventor: Kaoru NAGASAWA, Toyota-shi (JP)

(73) Assignee: TOYOTA JIDOSHA KABUSHIKI KAISHA, Toyota-shi (JP)

(21) Appl. No.: 13/975,666

(22) Filed: Aug. 26, 2013

(30) Foreign Application Priority Data
Sep. 3, 2012 (JP) 2012-193456

(51) Int. Cl. H01L 23/00; H01L 21/02

(52) U.S. Cl. CPC H01L 23/562; H01L 21/02107
USPC 257/635; 438/761

(57) ABSTRACT

A semiconductor device includes a semiconductor substrate, an insulator film that is arranged above the semiconductor substrate, a first passivation film that is arranged above the insulator film, a second passivation film that is arranged above the first passivation film, a stress relaxation layer that is arranged above the second passivation film, an organic coated film that is arranged above the stress relaxation layer, and a resin layer that is arranged above the organic coated film, wherein a Young's modulus of the stress relaxation layer is smaller than a Young's modulus of the organic coated film, and is smaller than a Young's modulus of the second passivation film.

### INCORPORATION BY REFERENCE

The disclosure of Japanese Patent Application No. 2012-193456 filed on Sep. 3, 2012 including the specification, drawings and abstract is incorporated herein by reference in its entirety.

### BACKGROUND OF THE INVENTION

1. Field of the Invention

The invention relates to a semiconductor device and a method of manufacturing the same.

2. Description of Related Art

In a semiconductor device, with a view to protecting a semiconductor element, a passivation film (e.g., a silicon nitride film) is formed on a semiconductor substrate via an insulator film. An organic coated film is formed above the passivation film, and moreover, is packaged with resin or the like. For example, the organic coated film is a polyimide film as a kind of the passivation film. When the semiconductor device is heated and soldered, absorbed moisture in the semiconductor device is rapidly gasified through heating at the time of soldering. Peeling occurs on an interface between the organic coated film and resin due to a stress generated as a result of a vapor pressure of the gasified moisture. As a result, a crack may be created in the resin. This crack deteriorates the reliability of the semiconductor device. Thus, Japanese Patent Application Publication No. 7-278301 (JP-7-278301 A) discloses an art of preventing peeling on an interface between polyimide and resin at the time of soldering, and preventing a crack from being created in the resin.

In Japanese Patent Application Publication No. 7-278301 (JP-7-278301 A), polyamide having relatively high adhesiveness to a resin layer is generated when a polyimide film is formed. Thus, the adhesiveness between an organic coated film containing polyamide (hereinafter referred to also as a polyamide film) and the resin layer is enhanced. As a result, a crack can be restrained from being created in the resin layer. However, polyamide has a much larger linear expansion coefficient than polyimide. In recent years, the operable temperature range required of a semiconductor device has been constantly widening. Therefore, in the semiconductor device in which a polyamide film is formed, the thermal stress that results from a difference in linear expansion coefficient between the polyamide film and a semiconductor substrate also tends to be large. In the case where the temperature range in which the semiconductor device operates widens, a large thermal stress is also applied to a passivation film that is located between the polyamide film and the semiconductor substrate. As a result, a crack may be created in the passivation film. In particular, a crack is likely to be created in the passivation film that is formed on a surface of an insulator film on the semiconductor substrate. This is because the linear expansion coefficients of the semiconductor substrate and the insulator film are smaller than the linear expansion coefficient of the passivation film that is formed on the surface of the insulator film, and a large thermal stress is applied to the passivation film. As described hitherto, in the art of Japanese Patent Application Publication No. 7-278301 (JP-7-278301 A), a crack may be created in the passivation film due to a thermal stress resulting from a change in outside temperature.

### SUMMARY OF THE INVENTION

The invention provides an art of restraining a crack from being created in a passivation film due to a thermal stress of an organic coated film.

A semiconductor device according to a first aspect of the invention includes a semiconductor substrate, an insulator film that is arranged above the semiconductor substrate, a first passivation film that is arranged above the insulator film, a second passivation film that is arranged above the first passivation film, a stress relaxation layer that is arranged above the second passivation film, an organic coated film that is arranged above the stress relaxation layer, and a resin layer that is arranged above the organic coated film. In this semiconductor device, a Young's modulus of the stress relaxation layer is smaller than a Young's modulus of the organic coated film, and is smaller than a Young's modulus of the second passivation film.

According to the foregoing aspect of the invention, a crack can be restrained from being created in the first passivation

A method of manufacturing a semiconductor device according to a second aspect of the invention includes forming an insulator film above a semiconductor substrate, foaming a first passivation film above the insulator film, forming a second passivation film above the first passivation film, forming a stress relaxation layer above the second passivation film, forming an organic coated film above the stress relaxation layer, and forming a resin layer above the organic coated film. In this method of manufacturing the semiconductor device, the stress relaxation layer is formed of a material having a Young's modulus that is smaller than a Young's modulus of the organic coated film and a Young's modulus of the second passivation film.

Owing to the foregoing aspect of the invention, the semiconductor device having the first passivation film in which a crack is unlikely to be created can be manufactured.

### BRIEF DESCRIPTION OF THE DRAWINGS

Features, advantages, and technical and industrial significance of an exemplary embodiment of the invention will be described below with reference to the accompanying drawings, in which like numerals denote like elements, and wherein:

FIG. 1 shows a longitudinal cross-section of a semiconductor device according to the invention;

FIG. 2 shows a longitudinal cross-section of a semiconductor device according to the related art in the vicinity of an electrode at a low temperature;

FIG. 3 shows a state in which a crack is created in a passivation film of the semiconductor device of FIG. 2;

FIG. 4 shows a longitudinal cross-section of the semiconductor device according to the invention in the vicinity of an electrode;

FIG. 5 shows a state in which an insulator film and the electrode are formed on a semiconductor substrate in a method of manufacturing the semiconductor device according to the invention;

FIG. 6 shows a state in which a nitride film is formed on surfaces of the electrode and the insulator film in the method of manufacturing the semiconductor device according to the invention; and

FIG. 7 shows a state in which a polyimide film is formed on surfaces of the electrode, the insulator film, and the nitride film, a fluororubber layer is formed on a surface of the polyimide film, a polyamide film is fanned on a surface of the fluororubber layer, and a resin layer is formed on a surface of the polyamide film in the method of manufacturing the semiconductor device according to the invention.

### DETAILED DESCRIPTION OF EMBODIMENT

In the semiconductor device of the invention, an adhesiveness between the organic coated film and the resin layer may be higher than an adhesiveness between the second passivation film and the resin layer. Thus, even when various stresses are generated inside the semiconductor device, the resin layer can be restrained from peeling off from a contact face.

In the semiconductor device of the invention, the first passivation film may be semi-conductive. Thus, inductive charges can be restrained from being created on a surface of the semiconductor substrate through the flow of electric charges via the first passivation film when mobile ions enter an upper layer of the first passivation

In the semiconductor device of the invention, the first passivation film may be formed in a peripheral withstand voltage region. Thus, mobile ions can be appropriately restrained from entering the vicinity of the semiconductor substrate (especially a region having a resurf structure).

In the semiconductor device of the invention, the organic coated film may contain polyamide. Thus, the resin layer can be restrained from peeling off from the organic coated film. Besides, the thermal stress that is applied to the stress relaxation layer by the film containing polyamide as a result of a change in outside temperature is appropriately absorbed by the stress relaxation layer. Thus, a crack can be restrained from being created in the first passivation film.

In the semiconductor device of the invention, the second passivation film may contain polyimide. Thus, a crack can be appropriately restrained from being created in the first passivation film.

In the semiconductor device of the invention, a metal layer may further be arranged on an upper face of the insulator film. In addition, the first passivation film may be arranged from the insulator film to the metal layer, and may be in contact with a surface of the insulator film and a surface of the metal layer. The semiconductor substrate may be formed rectangularly as viewed from above. The first passivation film may be formed of a nitride film. The second passivation film may be Ruined of polyimide. The organic coated film may be formed of polyamide. There may be established a relational expression:

$${E}_{k} < 1.041 \times \frac{t {2}^{2}}{Lt {1}^{2}} - 3.42 ( G Pa )$$

when it is assumed that E_{K} denotes a Young's modulus of the stress relaxation layer, that L denotes a length of a long side of the semiconductor substrate, that t1 denotes a film thickness of the metal layer, and that t2 denotes a film thickness of the first passivation film.

Since the Young's modulus of the stress relaxation layer satisfies the aforementioned relational expression, the stress relaxation layer can be deformed enough to appropriately absorb the thermal stress from the organic coated film. Thus, a crack can be restrained from being created in the first passivation film.

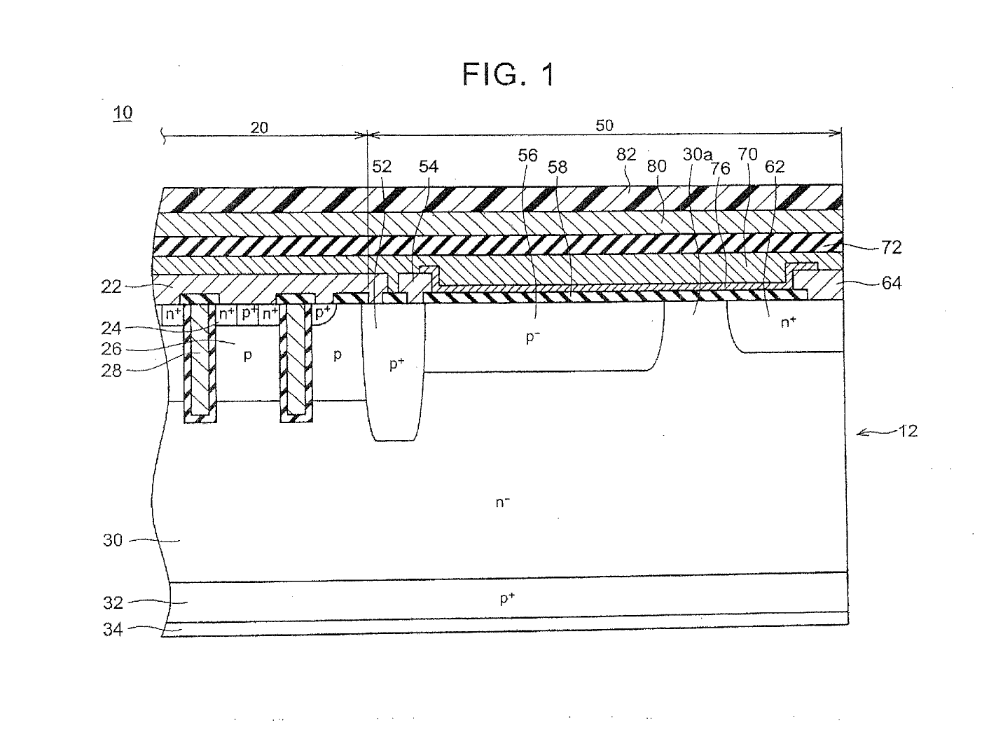

A semiconductor device according to the invention will be described. A semiconductor device 10 according to the invention shown in FIG. 1 is constituted of a semiconductor substrate 12, and electrodes, an insulator film and the like that are formed on upper and lower faces of the semiconductor substrate 12. The semiconductor substrate 12 is a rectangular substrate, and has an active region 20 and a peripheral withstand voltage region 50. An IGBT is formed in the active region 20. The active region 20 is formed substantially at a central portion of the semiconductor substrate 12 when the semiconductor substrate 12 is viewed from above. The peripheral withstand voltage region 50 is a region for alleviating an electric field of the active region 20, and is formed at an outer peripheral portion of the semiconductor substrate 12. More specifically, the peripheral withstand voltage region 50 is a region between an outer end face (i.e., an outer peripheral face) of the semiconductor substrate 12 and the active region 20. Accordingly, the active region 20 is surrounded by the peripheral withstand voltage region 50 when the semiconductor substrate 12 is viewed from above.

Trenches are formed in an upper face of the active region 20. Inner faces of the trenches are covered with gate insulator films respectively. Gate electrodes 28 are formed in the trenches respectively. An emitter electrode 22 is funned on the upper face of the active region 20. A lead frame (not shown) is soldered to the emitter electrode 22. More specifically, a conductive member is soldered onto the emitter electrode 22, and the lead frame is soldered onto this conductive member. The conductive member is, for example, a copper strut or a copper plate. A collector electrode 34 is formed on the lower face of the semiconductor substrate 12. A lead frame (not shown) is soldered on a lower face of the collector electrode 34 as well. That is, the lead frames are soldered to both the faces of the semiconductor substrate 12 respectively. Incidentally, electrodes on an upper face side of the semiconductor device 10 (e.g., the emitter electrode 22, gate electrode pads (not shown) (pads that are connected to the gate electrodes 28 respectively), and other signal fetch electrodes) are connected to an external conductive member through the use of a brazing filler material such as solder or the like, wire bonding, a conductive paste or the like.

N-type emitter regions 24, p-type body regions 26, an n-type drift region 30; and a p-type collector region 32 are formed in the active region 20. The emitter regions 24 are formed in such a range as to be exposed to the upper face of the semiconductor substrate 12. The emitter regions 24 are in contact with the gate insulator film covering the gate electrodes 28. The emitter regions 24 are ohmically connected to the emitter electrode 22. The body regions 26 are formed beside the emitter regions 24 and below the emitter regions 24 respectively. The body regions 26 are in contact with the gate insulator film below the emitter regions 24 respectively. Each of the body regions 26 (a so-called body contact region) between two adjacent ones of the emitter regions 24 has a high concentration of p-type impurities, and is ohmically connected to the emitter electrode 22. The drift region 30 is formed below the body regions 26. The drift region 30 is separated from the emitter regions 24 by the body regions 26. The drift region 30 is in contact with the gate insulator film at lower ends of the trenches. The collector region 32 is formed below the drift region 30. The collector region 32 has a high concentration of p-type impurities, and is ohmically connected to the collector electrode 34. The IGBT is formed in the active region 20 by the aforementioned respective electrodes and the aforementioned respective semiconductor regions.

A deep p-type region 52, a resurf region 56, and an end n-type region 62 are formed in the peripheral withstand voltage region 50. The deep p-type region 52 is located at a boundary between the active region 20 and the peripheral withstand voltage region 50. The deep p-type region 52 is formed in such a range as to be exposed to the upper face of the semiconductor substrate 12. The deep p-type region 52 is in contact with the body regions 26. The deep p-type region 52 is formed to a depth deeper than the gate electrodes 28 in the active region 20. The deep p-type region 52 contains p-type impurities at a high concentration, and is ohmically connected to an electrode 54 that is formed on the deep p-type region 52. The electrode 54 functions as “the metal layer”.

The resurf region 56 is adjacent to the deep p-type region 52. The resurf region 56 is formed in such a range as to be exposed to the upper face of the semiconductor substrate 12. The resurf region 56 is formed with a shallower depth than the deep p-type region 52. The concentration of p-type impurities in the resurf region 56 is lower than the concentration of p-type impurities in the deep p-type region 52. Besides, the concentration of p-type impurities in the resurf region 56 is lower than the concentration of n-type impurities in the end n-type region 62. The end n-type region 62 is formed in such a range as to be exposed to an end face of the semiconductor substrate 12 and to be exposed to the upper face of the semiconductor substrate 12. The end n-type region 62 contains a relatively high concentration of n-type impurities, and is ohmically connected to an electrode 64 that is formed on the end n-type region 62. The electrode 64 functions as “the metal layer”. The aforementioned drift region 30 is formed below the deep p-type region 52, the resurf region 56, and the end n-type region 62. That is, the drift region 30 spreads from the active region 20 to the peripheral withstand voltage region 50. Besides, the drift region 30 exists in a range between the resurf region 56 and the end n-type region 62 as well, and is exposed to the upper face of the semiconductor substrate 12 within the range. The drift region 30 between the resurf region 56 and the end n-type region 62 will be referred to hereinafter as a peripheral drift region 36a. The concentration of n-type impurities in the drift region 30 is lower than the concentration of n-type impurities in the end n-type region 62. In the peripheral withstand voltage region 50 as well, the collector region 32 is formed below the drift region 30.

An insulator film 58 is formed on a surface of the peripheral withstand voltage region 50. The insulator film 58 extends from the deep p-type region 52 to the end n-type region 62, and is formed on each of an upper face of the resurf region 56 and an upper face of the peripheral drift region 30a. The electrode 54 and the electrode 64 are formed on an upper face of the insulator film 58. The electrode 54 is in contact with the deep p-type region 52 via a through-hole that is formed through the insulator film 58. The electrode 64 is in contact with the end n-type region 62. Incidentally, the electrode 54 and the electrode 64 in this embodiment of the invention are made of aluminum, but the type of the metal of which the electrodes are formed is not limited thereto.

The insulator film 58 is located between the electrode 54 and the electrode 64, and a nitride film 76 is formed on the insulator film 58. The nitride film 76 is formed between the electrode 54 and the electrode 64. That is, the nitride film 76 is formed on a surface of the insulator film 58 in such a manner as to be in contact with at least part of a surface of the electrode 54 and to be in contact with at least part of a surface of the electrode 64. Accordingly, the nitride film 76 is formed on the surface of the peripheral withstand voltage region 50 as a continuous film, from the insulator film 58 to the electrode 54 and the electrode 64. The nitride film 76 functions as “the first passivation film”. Although the nitride film 76 in this embodiment of the invention is a semi-conductive silicon nitride film (a so-called SInSiN film), the substance of which the first passivation film is formed is not limited thereto.

A polyimide film 70 is formed on the surfaces of the electrode 54 and the electrode 64, a surface of the nitride film 76, and the surface of the insulator film 58. The polyimide film 70 is also in contact with part of an upper face of the emitter electrode 22. That is, the polyimide film 70 is formed as a layer that is continuous with part of the surface of the active region 20 and the surface of the peripheral withstand voltage region 50. The polyimide film 70 functions as “the second passivation film”. Incidentally, although the second passivation film is formed by the polyimide film 70 in this embodiment of the invention, the substance of which the second passivation film is formed is not limited thereto.

A fluororubber layer 72 is formed on an upper face of the polyimide film 70. The fluororubber layer 72 functions as “the stress relaxation layer”. The fluororubber layer 72 can be formed using, for example, Viton (registered trademark) manufactured by DuPont. Incidentally, although the fluororubber layer 72 is formed as the stress relaxation layer in this embodiment of the invention, the substance of which the stress relaxation layer is formed is not limited thereto. For example, the stress relaxation layer may be formed of silicon rubber. As silicon rubber, it is possible to use, for example, Bathcoke (registered trademark) manufactured by Cemedine Co., Ltd.

A polyamide film 80 is formed on an upper face of the fluororubber layer 72. The polyamide film 80 functions as “the organic coated film”. Although not shown in FIG. 1, the polyamide film 80 is formed on the end face of the semiconductor substrate 12 as well. That is, the polyamide film 80 is formed as a continuous film from the upper face of the fluororubber layer 72 to the end face of the semiconductor substrate 12. It should be noted herein that the Young's modulus of the polyamide film 80 is about 3.7 (GPa), that the Young's modulus of the fluororubber layer 72 is 0.035 to 0.055 (GPa), and that the Young's modulus of the polyimide film 70 is about 3.6 (GPa). Accordingly, the Young's modulus of the fluororubber layer 72 is smaller than the Young's modulus of the polyamide film 80, and is smaller than the Young's modulus of the polyimide film 70. Incidentally, although the organic coated film is formed by the polyamide film 80 in this embodiment of the invention, the substance of which the organic coated film is formed is not limited thereto.

A resin layer 82 is formed on an upper face of the polyamide film 80. Although not shown in FIG. 1, the resin layer 82 is also formed on the end face of the semiconductor substrate 12. That is, the resin layer 82 is formed in such a manner as to cover a surface of the polyamide film 80. As the resin layer 82, it is possible to use a thermosetting resin such as epoxy resin or the like. However, the substance of which the resin layer 82 is formed is not limited to such a thermosetting resin. The adhesiveness between the resin layer 82 and the polyamide film 80 is higher than the adhesiveness between the resin layer 82 and the polyimide film 70. Accordingly, by forming the polyamide film 80 such that the polyamide film 80 is in contact with the resin layer 82, the degree of adhesion between the resin layer 82 and the film with which the resin layer 82 is in contact is enhanced, so that the resin layer 82 is unlikely to peel off from the semiconductor substrate 12. Incidentally, as a method of evaluating the adhesiveness, for example, a tensile shear adhesion strength test can be used.

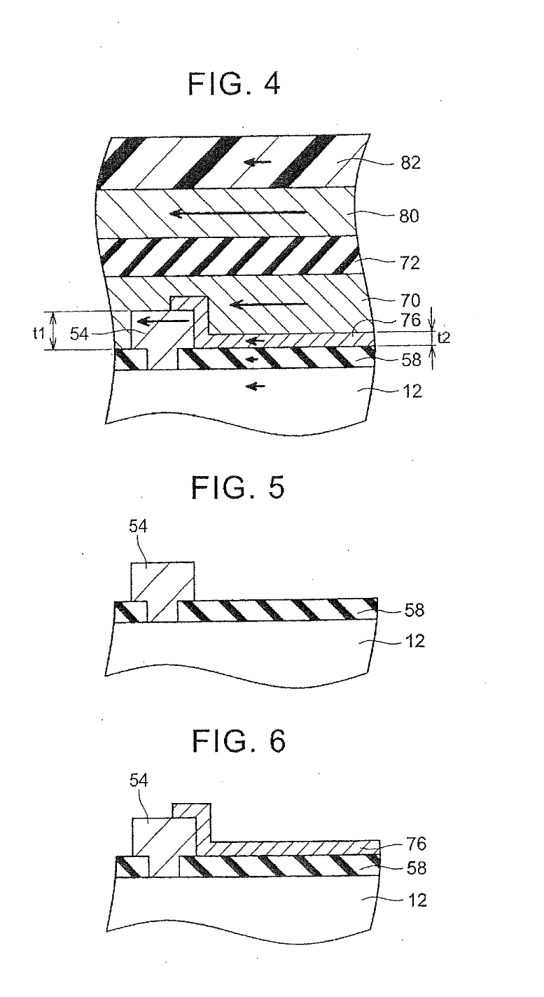

Now, a condition for preventing a crack from being created in the nitride film 76 in the aforementioned semiconductor device 10 will be described. The thermal stress applied to the semiconductor device 10 is determined by the temperature range in which the semiconductor device 10 is used. That is, the members such as the resin layer 82, the polyamide film 80, and the like, which are formed above the nitride film 76, are generally formed in a range of 160 to 180 (° C.). Thus, as the temperature rises or falls from the temperature at which the aforementioned members are formed, the thermal stress applied to the nitride film 76 from the polyamide film 80 increases. Accordingly, if a temperature range in which the semiconductor device 10 is used is set, the thermal stress is maximized when the temperature is equal to the lowest temperature of the set temperature range. Thus, it is appropriate to calculate a stress that is applied to the nitride film 76 at the lowest temperature, and ensure that the calculated stress is smaller than a yield stress of the nitride film 76. For example, if it is assumed that t1 (see FIG. 4) denotes a thickness of the electrodes (which mean the two electrodes between which the nitride film is formed), that t2 (see FIG. 4) denotes a thickness of the nitride film, that L denotes a length of the long side of the rectangular semiconductor substrate, and that E_{K} denotes a Young's modulus of the stress relaxation layer when the lowest temperature of the temperature range in which the semiconductor device 10 is used is a certain temperature that is equal to or lower than 0 (° C.) (e.g., a lowest temperature to which the semiconductor device 10 is exposed when used in a cold district), the following relational expression may be established in order to prevent a crack from being created in the nitride film 76.

$${E}_{k} < 1.041 \times \frac{t {2}^{2}}{Lt {1}^{2}} - 3.42 ( G Pa )$$

In the case where the aforementioned relational expression is established, no crack is created in the nitride film 76 even at a low temperature at which a relatively large thermal stress is applied. As a concrete example, in the case where the electrodes 54 and 64 and the nitride film 76 were formed on the semiconductor substrate 12 with L=12 (mm) such that t1=5 (μm) and that t2=1.1 (μm), the fluororubber layer 72 was used as the stress relaxation layer, and the outside temperature was set to a predetermined temperature equal to or lower than 0 (° C.) (e.g., the lowest temperature to which the semiconductor device is exposed when used in a cold district), no crack was created in the nitride film 76. At this time, the right side of the aforementioned inequality is 0.778 (GPa), and on the other hand, the Young's modulus of the fluororubber layer 72 is 0.035 to 0.055 (GPa). Therefore, the aforementioned relational expression is satisfied.

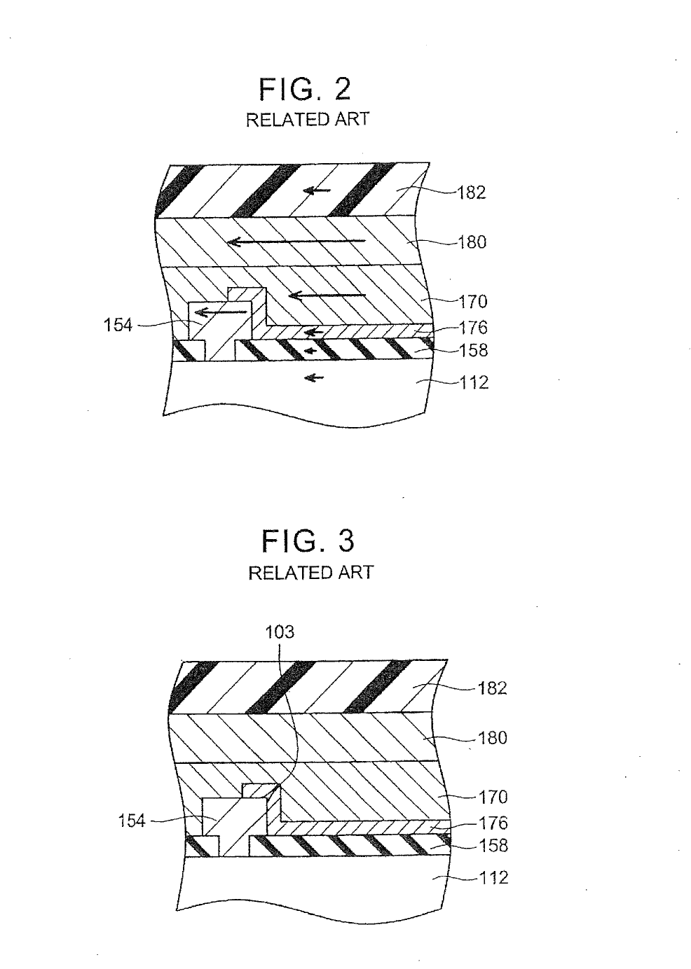

Next, the semiconductor device 10 according to the invention will be described while referring to a related semiconductor device as a comparative example, with reference to FIGS. 2 to 4. FIG. 2 is a partially enlarged view showing the related semiconductor device at a low temperature. Arrows shown in FIG. 2 schematically indicate the magnitudes of linear expansion coefficients of the respective members. The length of each of the arrows represents the magnitude of a linear expansion coefficient, whereas the ratios among the lengths of the respective arrows do not accurately reflect the magnitudes of linear expansion coefficients, but merely represent a relationship in magnitude among them. A thermal stress is applied to each of the members due to differences in linear expansion coefficient among the respective members. As the applied thermal stress, for example, a shear stress or a compressive stress can be mentioned, but the thermal stress is not limited thereto.

A semiconductor substrate 112, an insulator film 158, a nitride film 176, a polyimide film 170, a polyamide film 180, and a resin layer 182 in the related semiconductor device are formed of the same substances as the semiconductor substrate 12, the insulator film 58, the nitride film 76,.the polyimide film 70, the polyamide film 80, and the resin layer 82 in the semiconductor device 10 according to this embodiment of the invention, respectively. However, the related semiconductor device is different from the semiconductor device 10 according to this embodiment of the invention in that the fluororubber layer 72 is not formed. The linear expansion coefficients of the semiconductor substrate 112, the insulator film 158, the nitride film 176, the polyimide film 170, the polyamide film 180, and the resin layer 182 are about 3 (ppm/K), about 0.6 (ppm/K), about 3 (ppm/K), about 40 (ppm/K), about 80 (ppm/K), and about 9 (ppm/K). Polyamide has a larger linear expansion coefficient than polyimide. Therefore, a thermal stress that results from a difference in linear expansion coefficient between the polyamide film 180 and the polyimide film 170 is applied to the nitride film 176 as the outside temperature changes. This thermal stress increases as the temperature rises or falls from the temperature at which the resin layer 182, the polyamide film 180 and the like are formed. That is, the aforementioned thermal stress increases as the temperature falls within a temperature range in which the conventional semiconductor device is operable. Accordingly, at a low temperature, a large thermal stress is applied to the nitride film 176.

Besides, the nitride film 176 is formed above the semiconductor substrate 112 and the insulator film 158, and on the other hand, is formed below the polyimide film 170, the polyamide film 180, and the resin layer 182. Judging from the values of the aforementioned linear expansion coefficients, the linear expansion coefficients of the semiconductor substrate 112 and the insulator film 158 are far smaller than the linear expansion coefficients of the polyimide film 170, the polyamide film 180, and the resin layer 182. In other words, the nitride film 176 is formed between the members (a member group) with relatively large linear expansion coefficients and the members (a member group) with relatively small linear expansion coefficients. Thus, a thermal stress that results from a difference in linear expansion coefficient between the member group located above the nitride film 176 and the member group located below the nitride film 176 is applied to the nitride film 176 that is located therebetween. At a low temperature, the aforementioned thermal stress further increases. In the conventional semiconductor device, there is an apprehension that a crack 103 may be created in the nitride film 176 (see FIG. 3) due to these thermal stresses (a thermal stress resulting from a difference in linear expansion coefficient between the polyamide film 180 and the polyimide film 170, and a thermal stress resulting from a difference between the member group located above the nitride film 176 and the member group located below the nitride film 176).

It should be noted herein that FIG. 4 is a partially enlarged view of the semiconductor device according to the invention. The fluororubber layer 72 is formed between the polyimide layer 70 and the polyamide layer 80. The Young's modulus of the fluororubber layer 72 is smaller than the Young's modulus of the polyamide layer 80 formed on the upper face of the fluororubber layer 72, and is smaller than the Young's modulus of the polyimide film 70 formed on a lower face of the fluororubber layer 72. Therefore, the fluororubber layer 72 is relatively likely to be deformed. Thus, the displacement of the polyamide layer 80 is unlikely to be constrained by the fluororubber layer 72 at a low temperature. Accordingly, the thermal stress that is applied to the polyimide layer 70, which is funned below the fluororubber layer 72, by the polyamide layer 80 decreases. As a result, the thermal stress that results from the difference in linear expansion coefficient between the polyamide layer 80 and the polyimide layer 70, which is ascribable to a change in outside temperature (especially a fall in temperature), decreases. Besides, due to absorption of the thermal stress from the polyamide layer 80 by the fluororubber layer 72, the magnitude of the thermal stress that results from the difference in linear expansion coefficient between the member group that is formed above the nitride film 76 (i.e., the polyimide layer 70, the stress relaxation layer 72, the polyamide layer 80, and the resin layer 82) and the member group that is formed below the nitride film 76 (i.e., the semiconductor substrate 12 and the insulator film 58) also becomes smaller than in the conventional semiconductor device. These thermal stresses that are applied to the nitride film 76 become smaller than before, so that a crack can be restrained from being created in the nitride film 76.

In particular, in the semiconductor device 10 according to this embodiment of the invention, as shown in FIG. 1, the nitride film 76 is formed between the electrode 54 and the electrode 64. More specifically, the nitride film 76 is formed from the insulator film 58 to the electrodes 54 and 64, in such a manner as to be in contact with the surface of the insulator film 58, and to be in contact with the lateral faces of the electrodes 54 and 64 and parts of the upper faces of the electrodes 54 and 64. In other words, the nitride film 76 is formed in such a manner as to cover corner portions of the electrodes 54 and 64. Now, description will be given making a comparison with the related semiconductor device, with reference to FIG. 2. In the related semiconductor device as well, the nitride film 176 is arranged between an electrode 154 and an electrode 164 (not shown), in the same manner as the nitride film 76. Incidentally, the electrode 154 is formed of the same substance as the electrode 54, and the linear expansion coefficient of the electrode 154 is 24 (ppm/K). In the semiconductor device, when the aforementioned thermal stress is applied to the nitride film 176 as a result of a change in outside temperature (especially a fall in temperature), the crack 103 may be created in the nitride film 176 in the corner portions where a stress from the periphery thereof tends to concentrate, as shown in FIG. 3. Incidentally, this is not the only location where a crack is created. For example, a crack may also be created in a flexed portion of the nitride film 176 (a region in which the nitride film 176 is erected from the insulator film 158 to the lateral face of the electrode 154 in FIG. 3). In general, in a configuration in which a nitride film is formed in such a manner as to cover corner portions of an electrode, a stress concentrates on the corner portions, and hence, a crack is more likely to be created than in a configuration in which a nitride film is formed on a flat face. However, in the semiconductor device 10 according to this embodiment of the invention, the fluororubber layer 72 is formed between the polyamide film 80 and the polyimide film 70, and absorbs a thermal stress from the polyamide film 80. Accordingly, even in the configuration in which the nitride film 76 covers the corner portions of the electrode 54 (and the electrode 64 (not shown)) from the insulator film 58 to the electrode 54 (and the electrode 64 (not shown)), a thermal stress that is large enough to create a crack in the nitride film 76 can be restrained from being applied. That is, a crack can be restrained from being created in the nitride film 76.

Besides, by adjusting the Young's modulus of the stress relaxation layer, the thicknesses of the electrodes 54 and 64, the thickness of the nitride film 76, and the length of the long side of the rectangular semiconductor substrate 12 such that the foregoing relational expression is satisfied, the stress applied to the nitride film 76 becomes equal to or smaller than the yield stress of the nitride film 76, so that a crack can be restrained from being created in the nitride film 76. Besides, the adhesiveness between the polyamide film 80 and the resin layer 82 is higher than the adhesiveness between the polyimide film 70 and the resin layer 82. Therefore, even when various thermal stresses are applied to the resin layer 82, a crack can be restrained from being created in the resin layer 82, and the resin layer 82 can be restrained from peeling off from the polyamide film 80.

Besides, the nitride film prevents mobile ions such as Na, Cu, Cl and the like from entering the semiconductor substrate 12 from the outside. Accordingly, due to the formation of the nitride film 76 in the peripheral withstand voltage region 50, mobile ions can be prevented from entering the vicinity of the resurf region 56. In particular, as shown in FIG. 1, the nitride film 76 is formed between the electrode 54 and the electrode 64 as a continuous film, whereby mobile ions can be reliably prevented from entering the vicinity of the resurf region 56.

Furthermore, since the nitride film is semi-conductive, inductive charges can be restrained from being generated on the surface of the semiconductor substrate 12. Thus, the withstand voltage performance of the peripheral withstand voltage region can be restrained from decreasing. In particular, the nitride film 76 is formed across a space between the electrode 54 and the electrode 64 as shown in FIG. 1, whereby inductive charges can be reliably restrained from being generated on the surface of the semiconductor substrate 12. Accordingly, the withstand voltage performance of the peripheral withstand voltage region can be restrained from decreasing.

As described above, the semiconductor device 10 according to this embodiment of the invention makes it possible to restrain a crack from being created in the nitride film 76 due to a thermal stress.

Next, a method of manufacturing the semiconductor device 10 will be described with reference to FIGS. 5 to 7. Although not shown in the drawings, a semiconductor element structure such as a diffusion layer or the like is formed in the active region 20 of the semiconductor substrate 12. Methods of forming the semiconductor element structure in the active region 20 are conventionally known. Therefore, the description of those methods is omitted. In the following description, a method of forming a protective film that is provided on the surface of the peripheral withstand voltage region 50 of the semiconductor substrate 12 will be mainly described. Besides, in the drawings mentioned below, only the vicinity of the electrode 54 is depicted, but the following manufacturing method is common in the peripheral withstand voltage region 50. In this embodiment of the invention, the semiconductor substrate 12 is subjected to an insulator film formation process, a metal layer formation process, a first passivation film formation process, a second passivation film formation process, a stress relaxation layer formation process, an organic coated film formation process, and a resin layer formation process, whereby the semiconductor device 10 is manufactured.

(Insulator Film Formation Process)

First of all, as shown in FIG. 5, the insulator film 58 is formed on the surface of the semiconductor substrate 12 according to a known method. Then, the insulator film 58 is etched through the use of photolithography technologies or the like, so that the patterned insulator film 58 is formed.

(Metal Layer Formation Process)

Then, as shown in FIG. 5, an aluminum layer is formed on the surfaces of the insulator film 58 and the semiconductor substrate 12 according to a CVD method or the like. Incidentally, a barrier layer may be formed in advance between the aluminum layer and the insulator film 58 and between the aluminum layer and the semiconductor substrate 12. After that, the aluminum layer is etched through the use of photolithography technologies or the like, so that the electrode 54 is formed. Incidentally, the electrode 64 (not shown) is also formed in a similar manner.

(First Passivation Film Formation Process)

Subsequently, as shown in FIG. 6, the nitride film 76 is formed on the surface of the insulator film 58 and the surface of the electrode 54 through the use of a plasma CVD method or the like. The method of forming the nitride film 76 is not limited to the plasma CVD method. For example, a radical beam method or the like may be employed to form the nitride film 76. The nitride film 76 thus formed is continuously formed from the electrode 54 to the insulator film 58, and is in contact with the surface of the insulator film 58 and in contact with the lateral face of the electrode 54 and part of the upper face of the electrode 54.

(Second Passivation Film Formation Process)

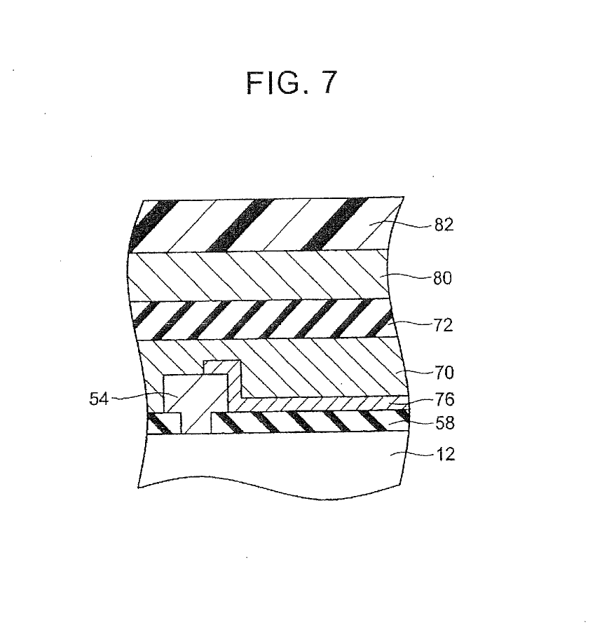

Subsequently, the surface of the semiconductor substrate 12 is coated with an organic solvent containing polyimide according to a method such as spin coating or the like, and is dried to form a polyimide coated film. Then, the polyimide coated film is subjected to a polyimide bake treatment to be calcined, so that the polyimide film 70 as shown in FIG. 7 is formed. The polyimide bake treatment is performed within a temperature range of for example, 160 to 180 (° C.). Incidentally, part of the polyimide film 70 that is formed on the surface of the active region 20 is removed through etching, in order to subsequently arrange the lead frame on the element of the active region 20. The polyimide coated film contracts at a certain rate through the polyimide bake treatment. It is therefore desirable to adjust the height of the polyimide coated film in advance such that the polyimide film 70 covers the upper face of the nitride film 76 and the, upper face of the insulator film 58 as shown in FIG. 7. The polyimide film 70 thus formed is continuously formed from the nitride film 76 to the insulator film 58 via the electrode 54 (and the electrode 64 and part of the emitter electrode 22), and is in contact with the surface of the nitride film 76, the surface of the electrode 54 (and the surface of the electrode 64 and part of the surface of the emitter electrode 22) and the surface of the insulator film 58.

(Stress Relaxation Layer Formation Process)

Subsequently, the surface of the semiconductor substrate 12 is coated with fluororubber according to a method such as spin coating or the like, and is dried to form the fluororubber layer 72 as shown in FIG. 7. The fluororubber layer 72 can be formed using, for example, Viton (registered trademark) manufactured by DuPont. Incidentally, part of the fluororubber layer 72 that is formed on the surface of the active region 20 is removed through etching in order to subsequently arrange the lead frame on the element of the active region 20. The fluororubber layer 72 thus formed is in contact with the upper face of the polyimide film 70. Before proceeding to the next process, the lead frames are soldered to the surface of the semiconductor substrate 12 (more specifically, on the element of the active region 20) and a back face of the semiconductor substrate 12 (i.e., a back face of the collector electrode 34).

(Organic Coated Film Formation Process)

Subsequently, the semiconductor substrate 12 is immersed in the organic solvent containing polyamide (hereinafter referred to also as a polyamide liquid) and dried to form the polyamide film 80 as shown in FIG. 7. The polyamide film 80 thus formed is formed as a continuous film from the fluororubber layer 72 to the lead frame, in such a manner as to be in contact with the surface of the fluororubber layer 72, the end face of the semiconductor substrate 12, and that region of the lead frame which is immersed in the polyamide liquid. Incidentally, the Young's modulus of polyamide is about 3.7 (GPa), and the Young's modulus of fluororubber (e.g., Viton (registered trademark)) is 0.035 to 0.055 (GPa). Accordingly, in the semiconductor device 10 according to this embodiment of the invention, the organic coated film and the stress relaxation layer are formed using a material that makes the Young's modulus of the stress relaxation layer smaller than the Young's modulus of the organic coated film.

(Resin Layer Formation Process)

Then, a thermosetting resin is injection-molded to seal the semiconductor substrate 12 with the resin. The method of injection molding is conventionally known, and therefore will not be described. For example, epoxy resin is used as the thermosetting resin. However, the thermosetting resin is not limited to epoxy resin. The resin layer 82 formed through injection molding is formed in such a manner as to cover the entire surface of the polyamide film 80 and part of the lead frame. After that, the polyamide film 80 and the resin layer 82, which are formed on the face on the other side of the face where the lead frame is in contact with the semiconductor substrate 12, are removed through the use of the CMP method or the like. Incidentally, the method of grinding is not limited to the CMP method.

According to the manufacturing method described above, the semiconductor device 10 shown in FIGS. 1 and 4 can be manufactured.

The embodiment of the invention has been described above in detail, but is nothing more than an exemplification. The semiconductor device and the method of manufacturing the semiconductor device of the invention encompass various modifications and alterations of the foregoing embodiment of the invention.

For example, the nitride film 76 is formed of the semi-conductive silicon nitride film (the SInSiN film) in the embodiment of the invention. However, the nitride film 76 may assume a double-layer structure having a silicon nitride film (SiN) on the upper face of the semi-conductive silicon nitride film (the SInSiN film). In this case, the silicon nitride film (SiN) as an upper-layer film of the nitride film 76 suppresses the entrance of mobile ions from the outside and serves as an insulator, and the semi-conductive silicon nitride film (the SInSiN film) as a lower-layer film of the nitride film 76 restrains inductive charges from being generated on the surface of the substrate, utilizing the nature of semi-conductivity. That is, this passivation film is formed in the peripheral withstand voltage region 50, whereby mobile ions from the outside can be restrained from entering the vicinity of the resurf region 56. In particular, this passivation film is formed between the electrode 54 and the electrode 64, whereby mobile ions from the outside can be reliably restrained from entering the vicinity of the resurf region 56. Incidentally, as is apparent from the function of the aforementioned nitride film 76, it suffices that the nitride film 76 be connected at one end thereof to the electrode 54, and at the other end thereof to the electrode 64. Thus, the nitride film 76 is not required to be formed on the upper face of the electrode 54, but may be formed only on the lateral face of the electrode 54. By the same token, the nitride film 76 is not required to be formed on the upper face of the electrode 64, but may be formed only on the lateral face of the electrode 64.

The concrete examples of the invention have been described above in detail, but are nothing more than exemplifications, and should not limit the claims. The invention encompasses various modifications and alterations of the concrete examples exemplified above. Besides, the technical elements described in the present specification or the drawings exert technical availability alone or in various combinations. Besides, the invention achieves a plurality of objects at the same time, and has technical availability by achieving one of the objects in itself.

What is claimed is:

1. A semiconductor device comprising:
a semiconductor substrate;
an insulator film that is arranged above the semiconductor substrate;
a first passivation film that is arranged above the insulator film;
a second passivation film that is arranged above the first passivation film;
a stress relaxation layer that is arranged above the second passivation film;
an organic coated film that is arranged above the stress relaxation layer; and
a resin layer that is arranged above the organic coated film, wherein
a Young's modulus of the stress relaxation layer is smaller than a Young's modulus of the organic coated film, and is smaller than a Young's modulus of the second passivation film.

2. The semiconductor device according to claim 1, wherein
an adhesiveness between the organic coated film and the resin layer is higher than an adhesiveness between the second passivation film and the resin layer.

3. The semiconductor device according to claim 1, wherein
the first passivation film is semi-conductive.

4. The semiconductor device according to claim 1, further comprising a peripheral withstand voltage region, wherein
the first passivation film is located in the peripheral withstand voltage region.

5. The semiconductor device according to claim 1, wherein
the organic coated film contains polyamide.

6. The semiconductor device according to claim 1, wherein
the second passivation film contains polyimide.

7. The semiconductor device according to claim 1, further comprising a metal layer that is arranged on an upper face of the insulator film, wherein
the first passivation film is arranged from the insulator film to the metal layer, and is in contact with a surface of the insulator film and a surface of the metal layer,
the semiconductor substrate is rectangular as viewed from above,
the first passivation film is formed of a nitride film,
the second passivation film is formed of polyimide,
the organic coated film is formed of polyamide, and
there is established a relational expression:
$${E}_{k} < 1.041 \times \frac{t {2}^{2}}{Lt {1}^{2}} - 3.42 ( G Pa )$$
when it is assumed that E_{K} denotes a Young's modulus of the stress relaxation layer, that L denotes a length of a long side of the semiconductor substrate, that t1 denotes a thickness of the metal layer, and that t2 denotes a thickness of the first passivation film.

8. A method of manufacturing a semiconductor, comprising:
forming an insulator film above a semiconductor substrate;
forming a first passivation film above the insulator film;
forming a second passivation film above the first passivation film;
forming a stress relaxation layer above the second passivation film;
forming an organic coated film above the stress relaxation layer; and
forming a resin layer above the organic coated film, wherein
the stress relaxation layer is formed of a material having a Young's modulus that is smaller than a Young's modulus of the organic coated film and a Young's modulus of the second passivation film.
